(19) United States
(12) Patent Application Publication
(10) Pub. No.: US 2025/0167089 A1
(43) Pub. Date: May 22, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Sungmin MOON, Suwon-si (KR); Pyoungwan KIM, Suwon-si (KR)

(73) Assignee: Samsung Electronics Co., Ltd., Suwon-si (KR)

(21) Appl. No.: 18/734,563

(22) Filed: Jun. 5, 2024

(30) Foreign Application Priority Data
Nov. 22, 2023 (KR) 10-2023-0162959

(51) Int. Cl. H01L 23/498; H01L 23/00; H01L 23/31; H01L 25/065

(52) U.S. Cl. CPC H01L 23/49827; H01L 23/3107; H01L 23/49822; H01L 24/24; H01L 25/0657; H01L 23/49816; H01L 24/16; H01L 24/32; H01L 24/73; H01L 2224/16225; H01L 2224/24; H01L 2224/32225; H01L 2224/73204

(57) ABSTRACT

A semiconductor package includes a lower redistribution wiring layer having first redistribution wirings, the lower redistribution wiring layer having a first region and a second region surrounding the first region, a semiconductor chip on the first region of the lower redistribution wiring layer and electrically connected to the first redistribution wirings, at least one bridge die stack on the second region of the lower redistribution wiring layer and including a plurality of bridge dies sequentially stacked on one another, each of the bridge dies including a plurality of through-vias that are electrically connected to the first redistribution wirings, a sealing member on the lower redistribution wiring layer covering the semiconductor chip and the at least one bridge die stack and an upper redistribution wiring layer on the sealing member and including second redistribution wirings electrically connected to the through-vias of the at least one bridge die stack.

### CROSS-REFERENCE TO RELATED APPLICATION

This application claims priority to and benefit under 35 U.S.C. § 119 to Korean Patent Application No. 10-2023-0162959, filed on Nov. 22, 2023 in the Korean Intellectual Property Office (KIPO), the disclosure of which is herein incorporated by reference in its entirety.

### BACKGROUND

Example embodiments relate to semiconductor packages and methods of manufacturing the semiconductor packages. More particularly, example embodiments relate to fan-out semiconductor packages and methods of manufacturing the same.

In a related manufacture of a fan-out package, a copper post may be formed on a lower redistribution wiring layer to be electrically connected to an upper redistribution wiring layer. The copper post has limitations in increasing its height due to limitations in a photo process and a plating process, and as the height of the copper post increases, a signal processing defect rate may increase. Further, when a thickness of the package increases, it is difficult to apply the copper post to electrical connections between chips.

### SUMMARY

Example embodiments provide semiconductor packages including a bridge die stack that replaces copper posts to enable finer vertical interconnection.

Example embodiments provide methods of manufacturing the semiconductor packages.

According to some example embodiments, a semiconductor package includes a lower redistribution wiring layer having first redistribution wirings, the lower redistribution wiring layer having a first region and a second region surrounding the first region; a semiconductor chip on the first region of the lower redistribution wiring layer and electrically connected to the first redistribution wirings; at least one bridge die stack on the second region of the lower redistribution wiring layer and including a plurality of bridge dies sequentially stacked on one another, each of the bridge dies including a plurality of through-vias that are electrically connected to the first redistribution wirings; a sealing member on the lower redistribution wiring layer covering the semiconductor chip and the at least one bridge die stack; and an upper redistribution wiring layer on the sealing member and including second redistribution wirings electrically connected to the through-vias of the at least one bridge die stack.

According to some example embodiments, a semiconductor package includes a package substrate; a first semiconductor chip on the package substrate; at least one bridge die stack spaced apart from the first semiconductor chip on the package substrate, the at least one bridge die including a plurality of through-vias that are each respectively electrically connected to substrate pads of the package substrate; and a second semiconductor chip on the first semiconductor chip and the at least one bridge die stack, the second semiconductor chip electrically connected to the through-vias.

According to some example embodiments, a semiconductor package includes a first redistribution wiring layer having first redistribution wirings, the first redistribution wiring layer having a chip mounting region and a peripheral region surrounding the chip mounting region; a semiconductor chip on the chip mounting region of the first redistribution wiring layer; a plurality of bridge die stacks on the peripheral region of the first redistribution wiring layer, each bridge die stack including a plurality of sequentially stacked bridge dies, each bridge die including a plurality of through-vias configured to be electrically connected to substrate pads of a package substrate; a sealing member covering the semiconductor chip and the plurality of bridge die stacks on the first redistribution wiring layer; and a second redistribution wiring layer on the sealing member and including a second redistribution wirings electrically connected to the through-vias.

According to some example embodiments, a semiconductor package as a fan-out wafer level package may include lower redistribution wiring layer, a semiconductor chip disposed on the lower redistribution wiring layer, at least one bridge die stack disposed on the lower redistribution wiring layer and includes sequentially stacked bridge dies, a sealing member covering the semiconductor chip and an upper redistribution wiring layer disposed on the sealing member.

According to some example embodiments a plurality of bridge die stacks passing through the sealing member may electrically connect the upper redistribution wiring layer and the lower redistribution wiring layer, the bridge die stack may include a plurality of sequentially stacked bridge dies, the plurality of bridge dies may include a plurality of through-vias, and the sequentially stacked through-vias of the plurality of bridge dies may be electrically connected to each other. Accordingly, fine vertical wiring is possible inside the bridge die stacks, which increases signal throughput and provides a semiconductor package with improved performance compared to copper posts based on the plating process.

According to some example embodiments, the bridge die stack may be provided as a vertical connection conductor for signal connection on behalf of copper posts in a 3D package or a 2.5D package.

According to some example embodiments the bridge die stack has fine wiring outside the semiconductor chip, and there is no need to have TSV inside the semiconductor chip, thereby increasing the integration of the semiconductor chip to increase the yield of the semiconductor chip and improving the performance of the semiconductor chip.

However, the effects of the present inventive concepts are not limited to the above-mentioned effects, and may be variously expanded without departing from the spirit and scope of the present inventive concepts.

### BRIEF DESCRIPTION OF THE DRAWINGS

Example embodiments will be more clearly understood from the following detailed description taken in conjunction with the accompanying drawings. FIGS. 1 to 24 represent non-limiting, example embodiments as described herein.

FIG. 1 is a cross-sectional view illustrating a semiconductor package in accordance with some example embodiments.

FIG. 2 is an enlarged cross-sectional view illustrating portion ‘A’ of FIG. 1.

FIG. 3 is a plan view illustrating a semiconductor package in accordance with some example embodiments.

FIG. 4 is an enlarged view illustrating portion ‘C’ of FIG. 3.

FIGS. 5 to 21 are views illustrating a method of manufacturing a semiconductor package in accordance with some example embodiments.

FIG. 22 is a cross-sectional view illustrating a semiconductor package in accordance with some example embodiments.

FIG. 23 is a plan view illustrating a first semiconductor chip and a bridge die stack disposed on a package substrate of FIG. 22.

FIG. 24 is a cross-sectional view illustrating a semiconductor package in accordance with some example embodiments.

### DETAILED DESCRIPTION

Hereinafter, some example embodiments will be explained in detail with reference to the accompanying drawings.

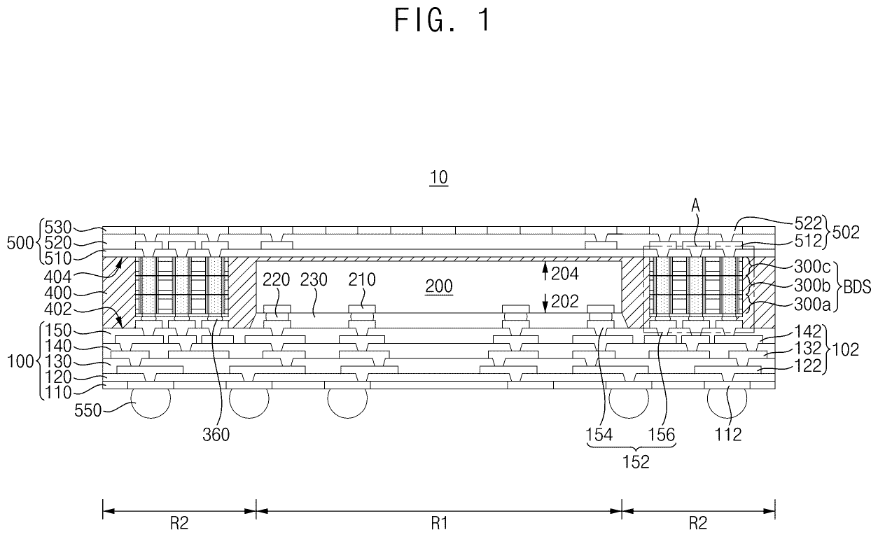

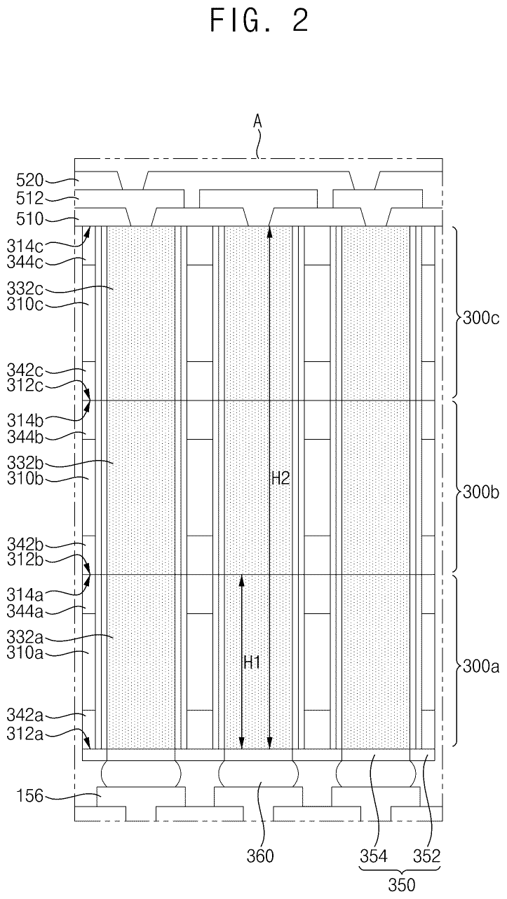

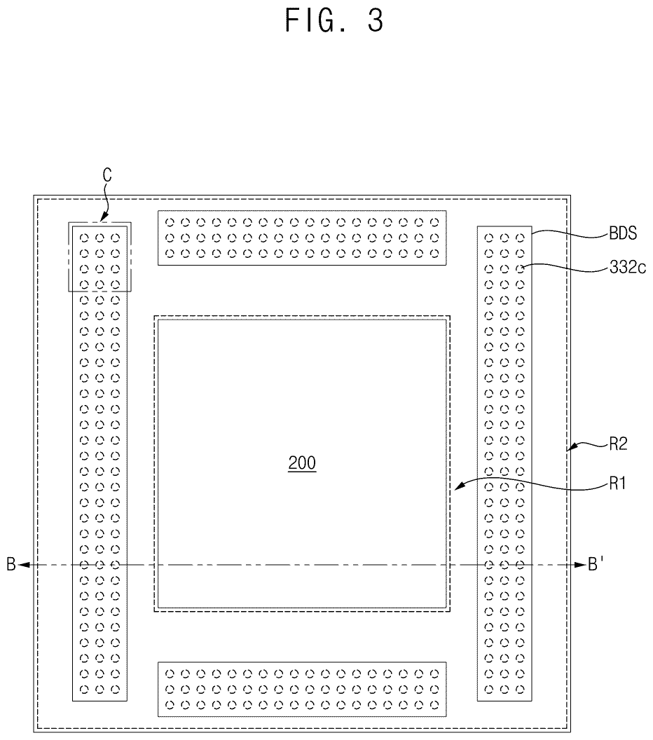

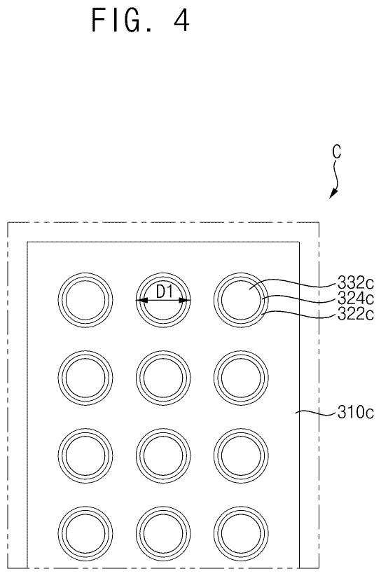

FIG. 1 is a cross-sectional view illustrating a semiconductor package in accordance with some example embodiments. FIG. 2 is an enlarged cross-sectional view illustrating portion ‘A’ of FIG. 1. FIG. 3 is a plan view illustrating the semiconductor package in FIG. 1. FIG. 4 is an enlarged view illustrating portion ‘C’ of FIG. 3. FIG. 1 is a cross-sectional view taken along the line B-B′ in FIG. 3.

Referring to FIG. 1, a semiconductor package 10 may include a lower redistribution wiring layer 100, a semiconductor chip 200 disposed on the lower redistribution wiring layer 100, a sealing member 400 covering at least a portion of the semiconductor chip 200 on an upper surface of the lower redistribution wiring layer 100, an upper redistribution wiring layer 500 disposed on an upper surface 404 of the sealing member 400, and at least one bridge die stack BDS penetrating the sealing member 400 to electrically connect the lower redistribution wiring layer 100 to the upper redistribution wiring layer 500. In addition, the semiconductor package 10 may further include external connection members 550 disposed on an outer surface of the lower redistribution wiring layer 100.

In some example embodiments, the semiconductor package 10 may be a fan-out package where the lower redistribution wiring layer 100 extends laterally to the sealing member 400 covering an outer side surface of the semiconductor chip 200. The lower redistribution wiring layer 100 may be formed by a wafer-level redistribution wirings process. Additionally, the semiconductor package 10 may be provided as a unit package on which a second package is stacked.

In addition, the semiconductor package 10 may be provided as a system in package (SIP). For example, one or more semiconductor chips may be disposed on the lower redistribution wiring layer 100. The semiconductor chips may include a logic chip including a logic circuit and/or a memory chip. The memory chip may include various types of memory circuits, such as random access memory (RAM), dynamic RAM (DRAM), static RAM (SRAM), flash, phase-change RAM (PRAM), resistive RAM (ReRAM), ferroelectric RAM (FeRAM), magnetoresistive RAM (MRAM), or combinations thereof.

In some example embodiments, the lower redistribution wiring layer 100 may have a first redistribution wirings 102. A semiconductor chip 200 may be disposed on the lower redistribution wiring layer 100 to be electrically connected to the first redistribution wirings 102. The lower redistribution wiring layer 100 may be provided on a front surface 202 of the semiconductor chip 200 to serve as a front redistribution wiring layer. Thus, the lower redistribution wiring layer 100 may be a front redistribution wiring layer FRDL of a fan-out package.

Particularly, the lower redistribution wiring layer 100 may include a plurality of first to fifth lower insulating layers 110, 120, 130, 140, and 150 and first redistribution wirings 102 provided in the first to fifth lower insulating layers. The first redistribution wirings 102 may include first to third lower redistribution wirings 122, 132, and 142.

The first to fifth lower insulating layers may include a polymer, a dielectric layer, etc. For example, the first to fifth lower insulating layers may include a photosensitive insulating layer such as a photo imageable dielectric (PID). The first to fifth lower insulating layers may be formed by a vapor deposition process, a spin coating process, etc. The first redistribution wirings may include aluminum (Al), copper (Cu), tin (Sn), nickel (Ni), gold (Au), platinum (Pt), or alloys thereof. The first redistribution wirings may be formed by a plating process, an electroless plating process, a vapor deposition process, etc.

Specifically, a first bonding pad 112 may be provided in the first lower insulating layer 110. The first bonding pad 112 may be a bump pad. The bump pad may include a solder pad or a pillar pad. For example, the first bonding pad may include copper (Cu), aluminum (Al), tin (Sn), nickel (Ni), gold (Au), platinum (Pt), or an alloy thereof.

The second lower insulating layer 120 may be formed on the first lower insulating layer 110, and the first lower redistribution wiring 122 may be formed on the second lower insulating layer 120. The first lower redistribution wiring 122 may be electrically connected to the first bonding pad 112 through a first opening formed in the second lower insulating layer 120.

The third lower insulating layer 130 may be formed on the second lower insulating layer 120, and the second lower redistribution wiring 132 may be formed on the second lower insulating layer 120. The second lower redistribution wiring 132 may be electrically connected to the first lower redistribution wiring 122 through a second opening formed in the third lower insulating layer 130.

The fourth lower insulating layer 140 may be formed on the third lower insulating layer 130, and the third lower redistribution wiring 142 may be formed on the third lower insulating layer 130. The third lower redistribution wiring 142 may be electrically connected to the second lower redistribution wiring 132 through a third opening formed in the third lower insulating layer 130.

A second bonding pad 152 may be disposed on the third lower redistribution wiring 142. A solder resist layer 150 as the fifth lower insulating layer may be formed on the fourth lower insulating layer 140 to expose at least a portion of the second bonding pad 152. The solder resist layer 150 may serve as a passivation layer.

The number, sizes, arrangement, etc. of the lower insulating layers and the lower redistribution wirings of the lower redistribution wiring layer are provided as examples, and it can be understood that the example embodiments are not limited thereto.

In some example embodiments, the lower redistribution wiring layer 100 may include a first region R1 overlapping the semiconductor chip 200 mounted on an upper surface of the lower redistribution wiring layer 100 and a second region R2 surrounding the first region R1. The second region R2 may be a fan-out region outside the region where the semiconductor chip 200 is disposed.

The second bonding pads 152 may be exposed from the upper surface of the lower redistribution wiring layer 100. The second bonding pads 152 may include chip connection bonding pads 154 formed on the uppermost first redistribution wirings 142 located in the first region R1 and bridge connection bonding pads 156 formed on the uppermost first redistribution wirings 142 located in the second region R2.

In some example embodiments, the semiconductor chip 200 may have a plurality of chip pads 210 on the first surface 202, that is, an active surface. The semiconductor chip 200 may be mounted on the lower redistribution wiring layer 100 such that the first surface on which the chip pads 210 are formed faces the lower redistribution wiring layer 100. In some example embodiments, the semiconductor chip 200 may not include any through-silicon via (TSV).

The semiconductor chip 200 may be mounted on the lower redistribution wiring layer 100 by a flip chip bonding method. The semiconductor chip 200 may be mounted on the lower redistribution wiring layer 100 via conductive bumps 220. The conductive bump 220 may be disposed between the chip connection bonding pad 154 on the third lower redistribution wiring 142 of the lower redistribution wiring layer 100 and the chip pad 210 of the semiconductor chip 200 to electrically connect the semiconductor chip 200 to the first redistribution wirings 102. For example, the conductive bump 220 may include a pillar bump formed on the chip pad 210 of the semiconductor chip 200 and a solder bump formed on the pillar bump. Alternatively, the conductive bump 220 may include a solder bump formed on the chip pad 210 of the semiconductor chip 200. An underfill member 230 may be disposed between the semiconductor chip 200 and the lower redistribution wiring layer 100.

Although only a few chip pads are illustrated in the figures, it will be understood that the structure and arrangement of the chip pads are some example embodiments, and the example embodiments are not limited thereto. In addition, although one semiconductor chip is illustrated, a plurality of semiconductor chips may be stacked on the lower redistribution wiring layer, but the example embodiments are not limited thereto.

In some example embodiments, the sealing member 400 may cover at least a portion of the semiconductor chip 200 on the upper surface of the lower redistribution wiring layer 100. The sealing member 400 may include a first sealing portion covering the upper surface 204 of the semiconductor chip 200 and a second sealing portion covering the upper surface of the lower redistribution wiring layer 100 around the semiconductor chip 200.

For example, the sealing member 400 may include an epoxy mold compound (EMC). The sealing member 400 may be formed by a sealing process, a screen printing process, a lamination process, etc.

In some example embodiments, the bridge die stack BDS may extend in a vertical direction to penetrate the sealing member 400. The bridge die stack BDS may be formed on the bridge connection bonding pad 156 on the uppermost first redistribution wiring 142 located in the second region R2.

The bridge die stack BDS may be provided to penetrate the sealing member 400 to provide electrical connection paths. The bridge die stack BDS may serve as a through mold via TMV formed through the second sealing portion of the sealing member 400. That is, the bridge die stack BDS may be provided in the fan-out region R2 outside the region where the semiconductor chip 200 is disposed, to electrically connect the lower redistribution wiring layer 100 and the upper redistribution wiring layer 500.

In some example embodiments, the upper redistribution wiring layer 500 may include second redistribution wirings 502 disposed on the sealing member 400 and electrically connected to the bridge die stack BDS, respectively. The second redistribution wirings 502 may include upper redistribution wirings 512 and 522 stacked on the upper surface 404 of the sealing member 400 in at least two layers. The second redistribution wirings 502 may be disposed on the sealing member 400 to serve as a backside redistribution wirings. Thus, the upper redistribution wiring layer 500 may be a backside redistribution wiring layer (BRDL) of the fan-out package.

The second redistribution wirings 502 may include a first upper redistribution wirings 512 and a second upper redistribution wirings 522 that are stacked in two layers. In this case, the second upper redistribution wirings 522 may be uppermost second redistribution wirings among the second redistribution wirings.

A first upper insulating layer 510 may be provided on the upper surface 404 of the sealing member 400 and may have openings that expose the upper surface of the bridge die stack BDS. The first upper redistribution wirings 512 may be formed on the first upper insulating layer 510 and at least a portion thereof may contact, for example directly contact, the bridge die stack BDS through the openings.

A second upper insulating layer 520 may be provided on the first upper insulating layer 510 and may have openings that expose the first upper redistribution wirings 512. The second upper redistribution wirings 522 may be formed on the second upper insulating layer 520, and at least a portion thereof may be in contact, for example direct contact, with the first upper redistribution wirings 512 through the openings.

Although not shown in the figures, upper bonding pads may be provided on the second upper redistribution wirings 522 respectively. A third upper insulating layer 530 may be provided on the second upper insulating layer 520 and may expose at least portions of the upper bonding pads. The third upper insulating layer 530 may serve as a passivation layer.

For example, the first to third upper insulating layers may include a polymer, a dielectric layer, etc. The first to third upper insulating layers may include a photosensitive insulating material (PID), an insulating layer such as ABF, etc. The second redistribution wirings may include copper (Cu), aluminum (Al), tin (Sn), nickel (Ni), gold (Au), platinum (Pt), or alloys thereof.

The number, arrangement, etc. of the upper insulating layers and the upper redistribution wirings of the upper redistribution wiring layer are provided as examples, and it can be understood that the example embodiments are not limited thereto.

As illustrated in FIG. 2, the bridge connection bonding pads 156 exposed from the upper surface of the lower redistribution wiring layer 100 may be located in the second region R2. The bridge die stack BDS may extend upward on the bridge connection bonding pad 156. The bridge die stack BDS may include a plurality of stacked first to third bridge dies 300a, 300b, and 300c. Each of the first to third bridge dies 300a, 300b, and 300c may have a first height H1. The first height H1 may be within a range of 380 μm to 760 μm. The bridge die stack BDS may have a second height H2. The second height H2 may vary in accordance with a height difference between the lower redistribution wiring layer 100 and the upper redistribution wiring layer 500. The second height H2 may be adjusted by the first height H1 and the number of stacked bridge dies 300. Accordingly, the bridge die stack BDS may be applied to the semiconductor package regardless of the thickness of the semiconductor chip 200 mounted on the lower redistribution wiring layer 100.

In particular, the first bridge die 300a may include a first silicon substrate 310a and a plurality of first through-vias 332a penetrating the first silicon substrate 310a. The first bridge die 300a may further include a first insulating layer 342a provided in a first surface 312a of the first silicon substrate 310a and a second insulating layer 344a provided in a second surface 314a opposite to the first surface 312a of the first silicon substrate 310a. The first through-via 332a may penetrate the first silicon substrate 310a in a vertical direction, and may be exposed from the first surface 312a and the second surface 314a of the first silicon substrate 310a. The first through-via 332a may include copper (Cu). Accordingly, the first and second insulating layers 342a and 344a may expose both ends of the first through-via 332a.

Similarly, the second bridge die 300b may include a second silicon substrate 310b and a plurality of second through-vias 332b penetrating the second silicon substrate 310b. The second bridge die 300b may further include a first insulating layer 342b provided in a first surface 312b of the second silicon substrate 310b and a second insulating layer 344b provided in a second surface 314b of the second silicon substrate 310b. The second through-via 332b may penetrate the second silicon substrate 310b in a vertical direction and may be exposed from the first surface 312b and the second surface 314b of the second silicon substrate 310b. The second through-via 332b may include copper (Cu).

Similarly, the third bridge die 300c may include a third silicon substrate 310c and a plurality of third through-vias 332c penetrating the third silicon substrate 310c. The third bridge die 300c may further include a first insulating layer 342c provided in a first surface 312c of the third silicon substrate 310c and a second insulating layer 344c provided in a second surface 314c of the third silicon substrate 310c. The third through-via 332c may penetrate the third silicon substrate 310c in a vertical direction and may be exposed from the first surface 312c and the second surface 314c of the third silicon substrate 310c. The third through-via 332c may include copper (Cu).

The first through-vias 332a may be arranged in an array form in the first bridge die 300a. The second through-vias 332b may be arranged in an array form in the second bridge die 300b. The third through-vias 332c may be arranged in an array form in the third bridge die 300c. The arrangement of the first through-vias 332a of the first bridge die 300a, the arrangement of the second through-vias 332b of the second bridge die 300b, and the arrangement of the third through-vias 332c of the third bridge die 300c may correspond to each other. The plurality of first to third through-vias 332a, 332b, and 332c may be disposed on each of the silicon substrates 310a, 310b, and 310c at a density of 10,000 or more per 1 mm².

As illustrated in FIGS. 3 and 4, when viewed from a plan view, the bridge die stack BDS may be disposed in the second region R2 surrounding the first region R1 that overlaps the semiconductor chip 200. The bridge die stack BDS may be arranged adjacent to a side surface of the semiconductor chip 200 around the semiconductor chip 200. Each of the bridge die stacks BDS may have a rectangular shape having a short side and a long side.

Referring again to FIG. 4, each of the through-vias may have a circular shape when viewed from a plan view. A diameter of the through-via may be within a range of 100 μm to 300 μm.

As illustrated in FIG. 4, the third bridge die 300c may further include a dielectric layer 322c surrounding the third through-via 332c. The dielectric layer 322c may be formed by an atomic layer deposition (ALD) process or a chemical-vapor deposition (CVD) process, and may cover an inner surface of an opening formed in the third silicon substrate 310c. The dielectric layer 322c may include silicon oxide. Accordingly, the dielectric layer may prevent or reduce in likelihood the metal material of the through-via from being diffused into the silicon substrate or reacted with the silicon material.

In addition, the third bridge die 300c may further include a barrier layer 324c on the dielectric layer 322c surrounding the third through-via 332c. The barrier layer 324c may include a metal material. The barrier layer 324c may be formed by a metal plating process. The barrier layer 324c may include titanium nitride (TiN), titanium (Ti), nickel (Ni), tungsten (W), silver (Ag), chromium (Cr), or alloys thereof. The barrier layer 324 may serve as a seed layer. By forming the barrier layer 324c, it is possible to prevent or reduce in likelihood the material of the through-via from expanding to the dielectric layer and deteriorating insulation, and to prevent or reduce in likelihood the material of the through-via from being diffused into the silicon substrate together with the dielectric layer or reacting with a silicon material. Thicknesses of the dielectric layer 322c and the barrier layer 324c may be within a range of 5 to 10 nm. The first bridge die 300a and the second bridge die 300b may similarly each include a dielectric layer surrounding the respective first through-via 332a and second through-via 332b. Additionally, the first bridge die 300a and the second bridge die 300b may similarly each include a barrier layer surrounding the respective dielectric layers.

The first insulating layer 342 (342a, 342b, 3422c) and the second insulating layer 344 (344a, 344b, 344c) may be provided in the first surface 312 (312a, 312b, 312c) and the second surface 314 (314a, 314b, 314c) of the silicon substrate 310. The insulating layers 342 and 344 may be formed through an oxidation process. Referring back to FIG. 4, when viewed from a plan view, the first and second insulating layers 342 and 344 may be provided in regions other than a plurality of openings in which the plurality of through-vias 332 are provided in the silicon substrate 310. Thus, the first and second insulating layers 342 and 344 may expose the through-via 332. The first and second insulating layers 342 and 344 may be used for bonding between the bridge dies 300.

The bridge die stack BDS may include the plurality of bridge dies 300 (300a, 300b, 300c) stacked in a vertical direction. The plurality of first through-vias 332a exposed from the second surface 314a of the first silicon substrate 310a of the first bridge die 300a may be bonded, for example directly bonded, to the corresponding plurality of second through-vias 332b exposed from the first surface 312b of the second bridge die 300b. That is, the first to third through-vias 332a, 332b, and 332c sequentially stacked in the bridge die stack BDS may be electrically connected to each other. For example, the first, second, and third bridge dies 300a, 300b, and 300c of the bridge die stack BDS may be bonded, for example directly bonded, to each other by a wafer-to-wafer hybrid bonding process.

The second insulating layer 344a in the second surface 314a of the first silicon substrate 310a and the first insulating layer 342b in the first surface 312b of the second silicon substrate 310b may be bonded, for example directly bonded, to each other, and the first through-via 332a of the first silicon substrate 310a and the second through-via 332b of the second silicon substrate 310b may be bonded to each other by Cu—Cu hybrid bonding.

Similarly, the second insulating layer 344b in the second surface 314b of the second silicon substrate 310b and the first insulating layer 342c in the first surface 312c of the third silicon substrate 310c may be bonded, for example directly bonded, to each other, and the second through-via 332b of the second silicon substrate 310b and the third through-via 332c of the third silicon substrate 310c may be bonded to each other by Cu—Cu hybrid bonding.

The number of the stacked silicon substrates may be determined in consideration of a desired height of the bridge die stack BDS.

In some example embodiments, the bridge die stack BDS may further include a connection redistribution wiring layer 350 provided on the exposed surface of at least one bridge die 300. For example, as illustrated in FIG. 2, the connection redistribution wiring layer 350 may include connection pads 354 provided on the first surface 312a of the first bridge die 300a. The connection redistribution wiring layer 350 may include a passivation layer pattern 352 on the first surface 312a of the first bridge die 300a and the connection pads 354 electrically connected to the first through-vias 322a respectively.

The passivation layer pattern 352 is provided on the first surface 312a of the first bridge die 300a and may have openings that expose a plurality of first through-vias 332a of the bridge die stack BDS. The connection pads 354 may be formed in the openings of the passivation layer pattern 352, and at least a portion thereof may contact, for example directly contact, the through-vias 332a through the openings.

Referring again to FIG. 1, the bridge die stack BDS may be mounted on the second region R2 of the lower redistribution wiring layer 100 via second conductive bumps 360. Specifically, the connection pad 354 formed on the first surface 312a of the first silicon substrate 310a of the bridge die stack BDS may be electrically connected to the bridge connection bonding pad 156 by the second conductive bump 360. For example, the second conductive bumps 360 may include micro-bumps. Accordingly, the first redistribution wirings 102 of the lower redistribution wiring layer 100 may be electrically connected to the first to third through-vias 332a, 332b, and 332c sequentially stacked in the bridge die stack BDS.

In some example embodiments, the external connection members 550 may be disposed on the first bonding pads 112 on the outer surface of the lower redistribution wiring layer 100. For example, the external connection member 550 may include a solder ball. The solder ball may have a diameter of 300 μm to 500 μm. The semiconductor package 10 may be mounted on a module substrate (not shown) by using the solder balls as a medium to form a memory module.

As described above, the semiconductor package 10 as a fan-out wafer level package may include the lower redistribution wiring layer 100, the semiconductor chip 200 disposed on the lower redistribution wiring layer 100, the sealing member 400 covering at least a portion of the semiconductor chip 200 on the upper surface of the lower redistribution wiring layer 100, the bridge die stack BDS penetrating the sealing member 400, and the upper redistribution wiring layer 500 disposed on the upper surface 404 of the sealing member 400.

Accordingly, since micronized vertical wiring is possible through the plurality of through-vias 332a, 332b, and 332c stacked on each other inside the bridge die stack BDS, signal throughput increases and a semiconductor package with improved performance can be completed compared to a copper post based on the plating process.

Hereinafter, a method of manufacturing the semiconductor package of FIG. 1 will be described.

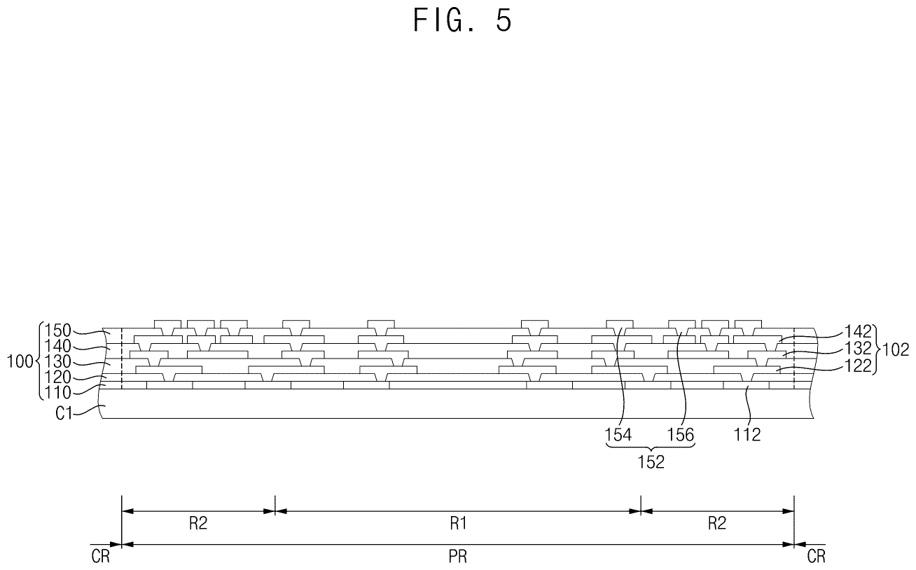

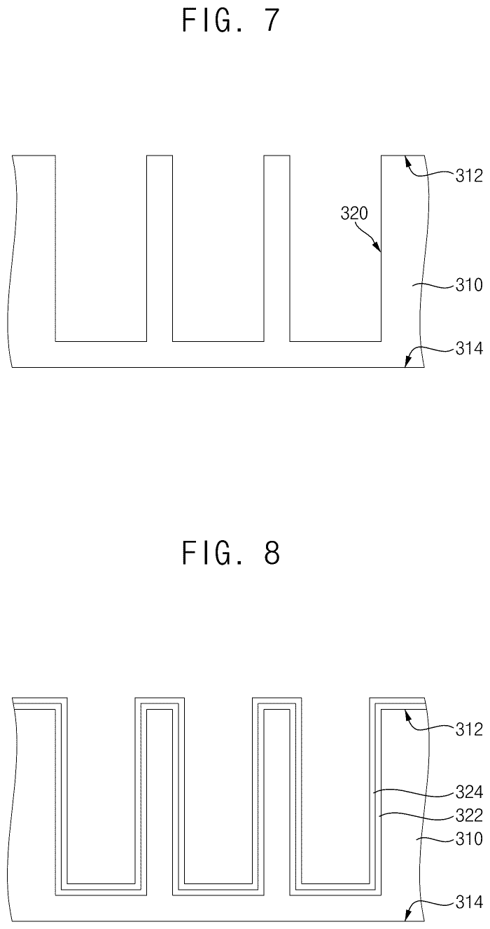

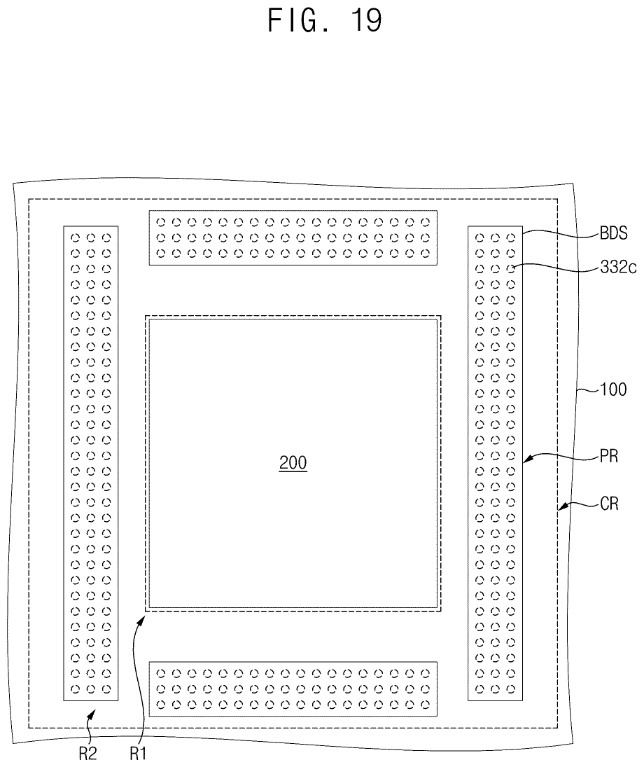

FIGS. 5 to 21 are views illustrating a method of manufacturing a semiconductor package in accordance with embodiments. FIGS. 7 to 17 are cross-sectional views illustrating processes of forming a plurality of bridge die stacks BDS. FIG. 19 is a plan view of FIG. 18.

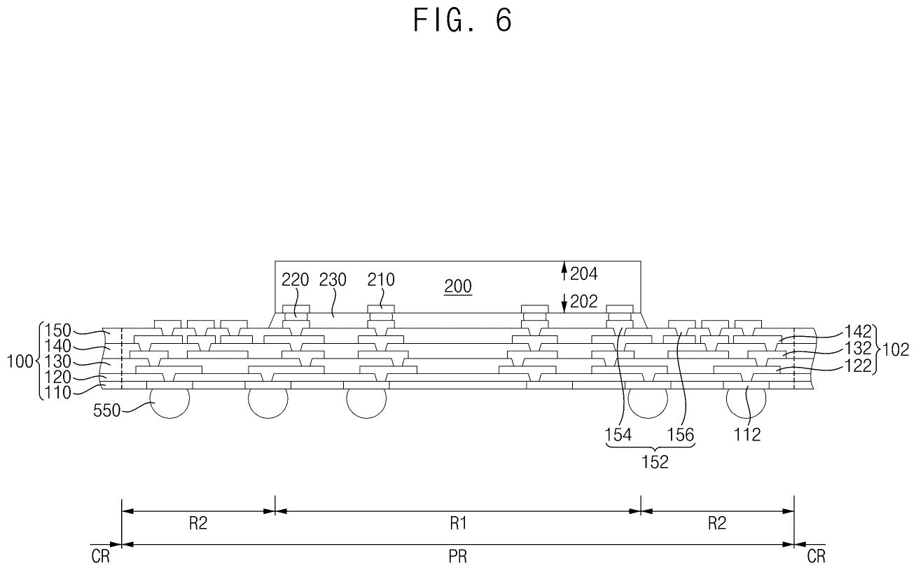

Referring to FIGS. 5 and 6, a lower redistribution wiring layer 100 having first redistribution wirings 102 may be formed on a carrier substrate C1.

In some example embodiments, the carrier substrate C1 may include a wafer substrate as a base substrate for disposing a plurality of semiconductor chips on the lower redistribution wiring layer and forming a sealing member covering the plurality of semiconductor chips. The carrier substrate C1 may have a shape corresponding to that of a wafer on which a semiconductor process is performed. For example, the carrier substrate C1 may include a silicon substrate, a glass substrate, a non-metal plate, or combinations thereof.

In some example embodiments, a first lower insulating layer 110 having first bonding pads 112 formed therein may be formed on the carrier substrate C1. Although not shown in the figures, a release layer, a barrier metal layer, a seed layer, and the first lower insulating layer may be formed on the carrier substrate C1, and then the first lower insulating layer may be patterned to form an opening that exposing a first bonding pad region. Subsequently, a plating process may be performed on the seed layer to form the first bonding pads 112 in the opening.

For example, the first lower insulating layer 110 may include a polymer, a dielectric layer, etc. The first lower insulating layer 110 may include a photosensitive insulating material (PID), an insulating layer such as ABF, etc. The first lower insulating layer may be formed by a spin coating process, a vapor deposition process, etc.

The first bonding pad 112 may be a bump pad. The bump pad may include a solder pad or a pillar pad. For example, the first bonding pad may include copper (Cu), aluminum (Al), tin (Sn), nickel (Ni), gold (Au), platinum (Pt), or an alloy thereof.

Subsequently, after forming a second lower insulating layer 120 on the first lower insulating layer 110 to cover the first bonding pads 112, the second lower insulating layer 120 may be patterned to form first openings that expose the first bonding pads 112, respectively.

For example, the second lower insulating layer 120 may include a polymer, a dielectric layer, etc. The second lower insulating layer 120 may include a photosensitive insulating material (PID), an insulating layer such as ABF, etc. The second lower insulating layer may be formed by a spin coating process, a vapor deposition process, etc.

Then, first lower redistribution wirings 122 may be formed on the second lower insulating layer 120 to contact, for example directly contact, the first bonding pads 112 through the first openings.

After forming a seed layer on a portion of the second lower insulating layer 120 and in the first opening, the seed layer may be patterned and an electroplating process may be performed to form the first lower redistribution wirings. Thus, at least a portion of the first lower redistribution wirings 122 may be in contact, for example direct contact, with the first bonding pads 112 through the first openings.

For example, the first lower redistribution may include copper (Cu), aluminum (Al), tin (Sn), nickel (Ni), gold (Au), platinum (Pt), or an alloy thereof.

Similarly, a third lower insulating layer 130 covering the first lower redistribution wirings 122 may be formed on the second lower insulating layer 120, and the third lower insulating layer 130 may be patterned to form second openings that expose at least portions of the first lower redistribution wirings 122. Subsequently, second lower redistribution wirings 132 may be formed on the third lower insulating layer 130 to be in contact, for example direct contact, with the first lower redistribution wirings 122 through the second openings.

Then, a fourth lower insulating layer 140 covering the second lower redistribution wirings 132 may be formed on the third lower insulating layer 130, and the fourth lower insulating layer 140 may be patterned to form third openings that expose at least portions of the first lower redistribution wirings 122. Then, third lower redistribution wirings 142 may be formed on the third lower insulating layer 130 to contact, for example directly contact, the second lower redistribution wirings 132 through the second openings.

Then, a fifth lower insulating layer 150 covering the third lower redistribution wirings 142 may be formed on the fourth lower insulating layer 140, and then the fifth lower insulating layer 150 may be patterned to form fourth openings that exposing at least portions of the third lower redistribution wirings 142.

Accordingly, the lower redistribution wiring layer 100 having the first to fifth lower insulating layers 110, 120, 130, 140, and 150 may be formed. The lower redistribution wiring layer 100 may be a front redistribution wiring layer (FRDL) of a fan-out package. The lower redistribution wiring layer 100 may include first redistribution wiring layers 102 stacked in at least two layers. The first bonding pads 112 may be exposed from a lower surface of the lower redistribution wiring layer 100.

When viewed from a plan view, the lower redistribution wiring layer 100 may include a package region PR on which the semiconductor chip is mounted and a cutting region CR surrounding the package region PR. As described later, the lower redistribution wiring layer 100 formed on the carrier substrate C1 may be cut along the cutting region CR that divides a plurality of the package regions PR to be individualized. Additionally, the lower redistribution wiring layer 100 may include a first region R1 overlapping the semiconductor chip to be mounted, and a second region R2 surrounding the first region R1. The second region R2 may be a fan-out region outside a region in which the semiconductor chip is disposed.

Subsequently, second bonding pads 152 may be formed on the uppermost first redistribution wirings 142 of the lower redistribution wiring layer 100.

For example, a seed layer may be formed on the fifth lower insulating layer 150, and a photoresist pattern having an opening that exposes a second bonding pad region may be formed on the seed layer. Subsequently, a plating process may be performed to form the second bonding pad 152 in the opening of the photoresist pattern. A portion of the second bonding pad 152 may be formed in the fourth opening of the fifth lower insulating layer 150.

Accordingly, the second bonding pads 152 may be formed on the uppermost first redistribution wirings 102 located in the first region R1 and the second region R2 of the lower redistribution wiring layer 100. The second bonding pads 152 may be exposed from an upper surface of the lower redistribution wiring layer 100. The second bonding pads 152 may include chip connection bonding pads 154 formed on the uppermost first redistribution wirings 142 located in the first region R1 and bridge connection bonding pads 156 formed on the uppermost first redistribution wirings 142 located in the second region R2.

Referring to FIG. 6, a semiconductor chip 200 may be mounted on the lower redistribution wiring layer 100.

In some example embodiments, the semiconductor chip 200 may be disposed in the first region R1 of the lower redistribution wiring layer 100. The semiconductor chip 200 may be mounted on the lower redistribution wiring layer 100 by a flip chip bonding method. The semiconductor chip 200 may be disposed on the front surface 202, on which the first chip pads 210 are formed, that is, an active surface thereof faces the lower redistribution wiring layer 100. The first chip pads 210 of the semiconductor chip 200 may be electrically connected to the first redistribution wirings 102 of the lower redistribution wiring layer 100 by the conductive bumps 220.

For example, the conductive bumps 220 may include a micro bump. The first conductive bump may include a pillar portion formed on the first chip pad and a solder portion formed on the pillar portion. The pillar portion may include copper (Cu), nickel (Ni), palladium (Pd), platinum (Pt), gold (Au), cobalt (Co), or alloys thereof. The solder portion may include tin (Sn), indium (In), antimony (Sb), copper (Cu), silver (Ag), zinc (Zn), lead (Pb), or alloy thereof.

An underfill member 230 may be underfilled between the semiconductor chip 200 and the lower redistribution wiring layer 100. The underfill member may include a material having relatively high fluidity to effectively fill the small space between the semiconductor chip and the first redistribution wiring layer. For example, the first underfill member may include an adhesive including an epoxy material.

The first semiconductor chip may be a logic chip including a logic circuit. The logic chip may be a controller that controls memory chips. The semiconductor chip may be a processor chip such as an ASIC or an application processor (AP) as a host such as CPU, GPU, and SOC.

Additionally, as depicted in FIG. 6, the carrier substrate C1 may be removed, and the external connection members 550 may be formed on the outer surface of the lower redistribution wiring layer 100, that is the first bonding pads 112 on the lower surface. However, the example embodiments are not so limited thereto. For example, the carrier substrate C1 may be removed and the external connection members 550 may be formed after the second redistribution wirings 502 are formed as described below.

Referring to FIGS. 7 to 18, at least one bridge die stack BDS including a plurality of stacked bridge dies 300 may be formed, and the at least one bridge die stack BDS may be disposed on the lower redistribution wiring layer 100.

As illustrated in FIG. 7, first, openings 320 may be formed in a first surface 312 of a silicon substrate 310 to partially penetrate the silicon substrate 310.

For example, a photoresist pattern covering the first surface 312 of the silicon substrate 310 and exposing the opening regions may be formed, and the silicon substrate 310 may be etched using the photoresist pattern as an etching mask to form the plurality of openings. The plurality of openings may have a circular cross-sectional shape.

As illustrated in FIG. 8, a dielectric layer 322 may be formed on the first surface 312 of the silicon substrate 310 and inner sidewalls of the openings 320 and a barrier layer 324 may be formed on a dielectric layer 322. The dielectric layer 322 may be formed by an atomic layer chemical deposition (ALD) process, a chemical vapor deposition (CVD) process, etc. The barrier layer 324 may be formed by a metal plating process. The barrier layer 324 may include titanium nitride (TiN), titanium (Ti), nickel (Ni), tungsten (W), silver (Ag), chromium (Cr), or alloys thereof.

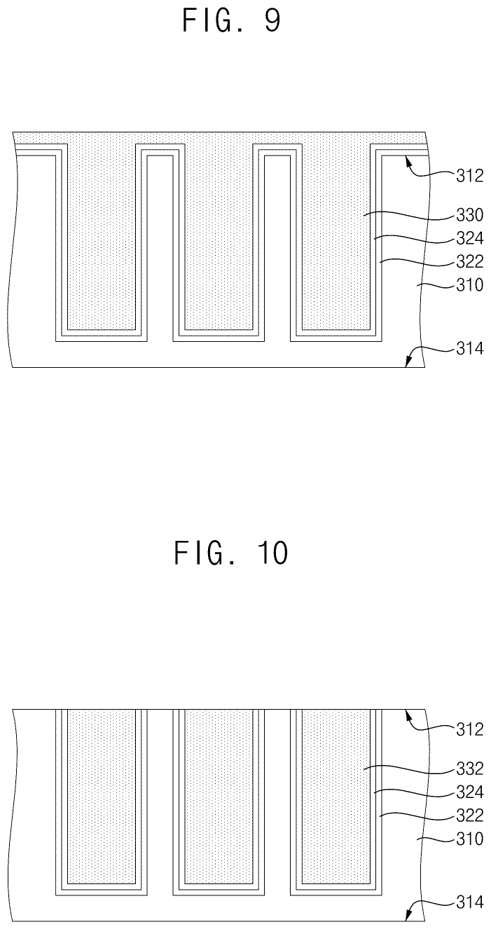

As illustrated in FIGS. 9 and 10, a conductive material 330 may be formed on the barrier layer 324 to sufficiently fill the openings 320, and the dielectric layer 322, the barrier layer 324, and the conductive material 330 may be planarized until the first surface 312 of the silicon substrate 310 is exposed, to form a through-via 332 that fills the opening. The conductive material 330 may include copper (Cu).

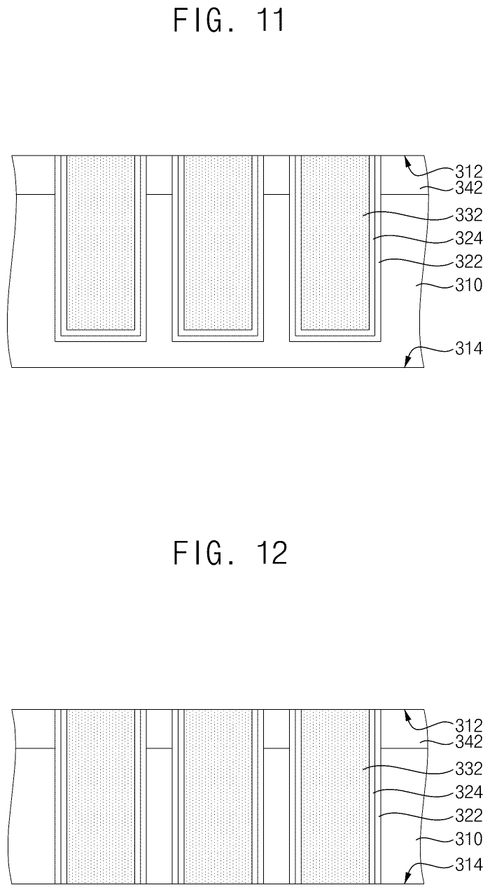

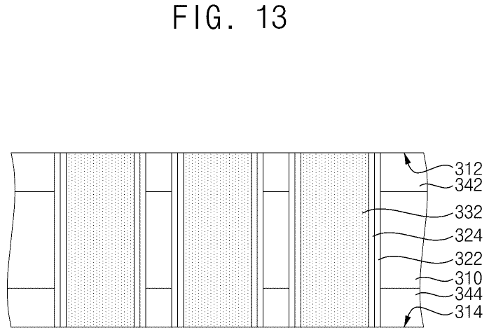

As illustrated in FIG. 11, a first insulating layer 342 may be formed in regions other than regions in which the plurality of openings are formed in the first surface 312 of the silicon substrate 310.

For example, a photoresist pattern covering the first surface 312 of the silicon substrate 310 and exposing a region other than the openings may be formed, a thermal oxidation process may be performed on the photoresist pattern, the photoresist pattern is removed, and the oxidizing material is planarized to form the first insulating layer 342. The first insulating layer 342 may include silicon carbide (SiCN), silicon oxide (SiO₂), etc. Accordingly, one end portion of the through-via 332 may be exposed by the first insulating layer 342.

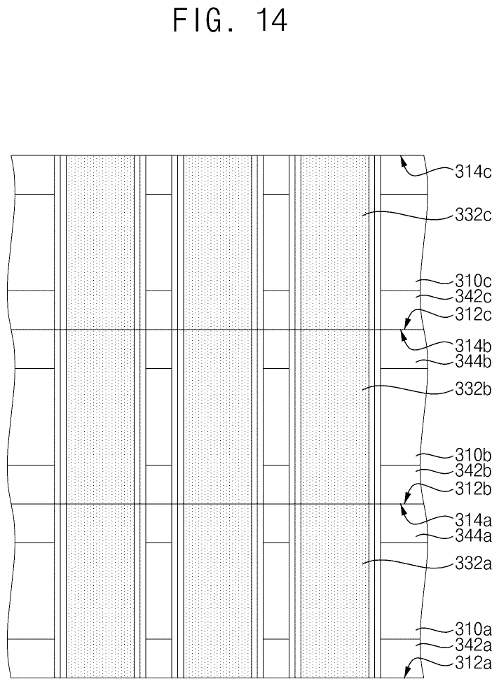

Then, as illustrated in FIG. 12, the structure of FIG. 11 may be reversed, and the second surface 314 of the silicon substrate 310 may be partially removed to expose the other end of the through-via 332. For example, after performing a grinding process such as a back lap process to partially remove the second surface 314 of the silicon substrate 310, an etching process such as a silicon recess process may be performed to expose the other end of the through-via 332. Accordingly, a thickness of the silicon substrate 310 may be reduced to a desired thickness.

As illustrated in FIG. 13, a second insulating layer 344 may be formed in a region other than a region in which the plurality of openings are formed in the second surface 314 of the silicon substrate 310. The second insulating layer may include silicon carbide (SiCN), silicon oxide (SiO₂), etc. Accordingly, the other end of the through-via 332 may be exposed by the second insulating layer 344.

As illustrated in FIG. 14, a plurality of silicon substrates 310 (310a, 310b, and 310c) may be stacked to have a desired height.

In some example embodiments, first, the second silicon substrate 310b may be bonded onto the first silicon substrate 310a (wafer-to-wafer hybrid bonding process). A thermal compression process and an annealing process may be performed to bond the first silicon substrate 310a and the second silicon substrate 310b to each other. That is, the second insulating layer 344a in the second surface 314a of the first silicon substrate 310a and the first insulating layer 342b in the first surface 312b of the second silicon substrate 310b may be bonded, for example directly bonded, to each other, and the first through-via 332a of the first silicon substrate 310a and the second through-via 332b of the second silicon substrate 310b may be bonded to each other by a copper-Cu hybrid bonding (Cu—Cu hybrid bonding).

Similarly, the third silicon substrate 310c may be bonded onto the second silicon substrate 310b (wafer-to-wafer hybrid bonding process). A thermal compression process and an annealing process may be performed to bond the second silicon substrate 310b and the third silicon substrate 310c to each other. That is, the second insulating layer 344b in the second surface 314b of the second silicon substrate 310b and the first insulating layer 342c in the first surface 312c of the third silicon substrate 310c are bonded, for example directly bonded, to each other, and the second through-via 332b of the second silicon substrate 310b and the third through-via 332c of the third silicon substrate 310c may be bonded to each other by a copper-Cu hybrid bonding process.

The number of the stacked silicon substrates may be determined in consideration of a desired height of the bridge die stack BDS.

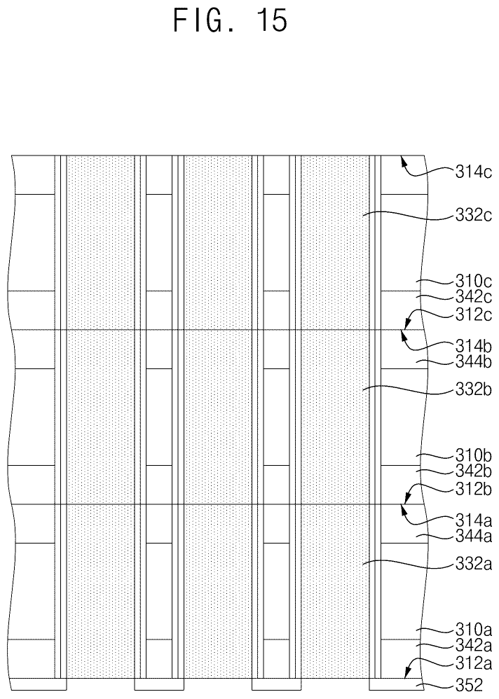

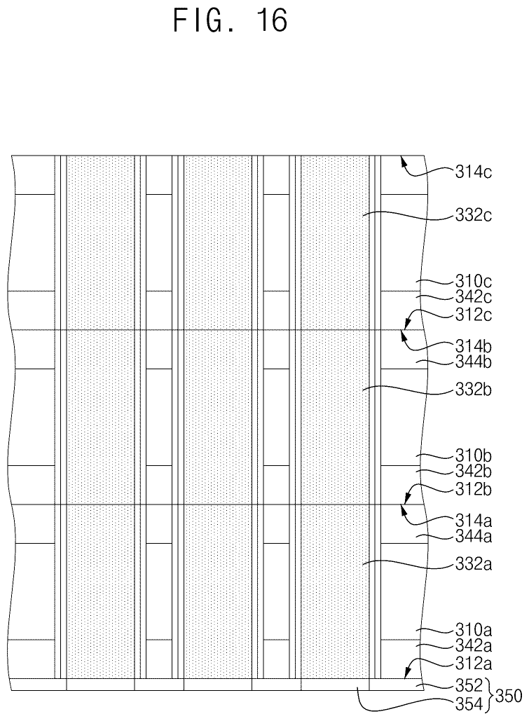

As illustrated in FIGS. 15 and 16, connection pads 354 may be formed on the first insulating layer 342a in the first surface 312a of the first silicon substrate 310a.

For example, a protective layer may be formed on the first insulating layer 342a on the first surface 312a of the first silicon substrate 310a, a photoresist pattern having an opening exposing the first through-via 332a may be formed on the protective layer, and a protective layer may be etched using the photoresist pattern as an etching mask to form a protective layer pattern 352 that expose the through-vias 332.

Subsequently, a plating process may be performed to form the connection pads 354 electrically connected to the first through-vias 332a. The connection pad may include copper (Cu), aluminum (Al), tin (Sn), nickel (Ni), gold (Au), platinum (Pt), or alloys thereof.

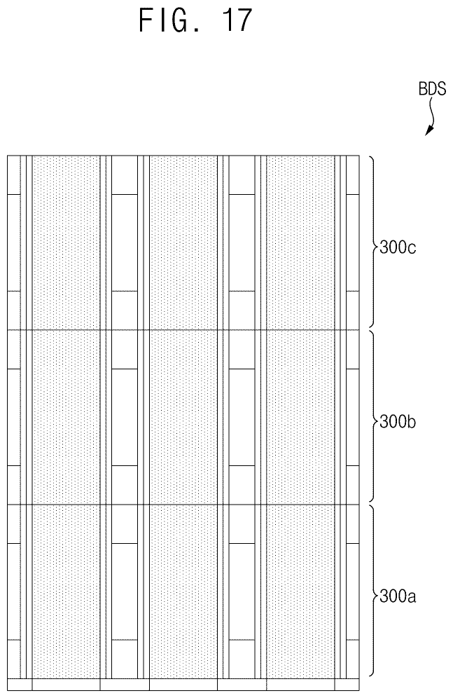

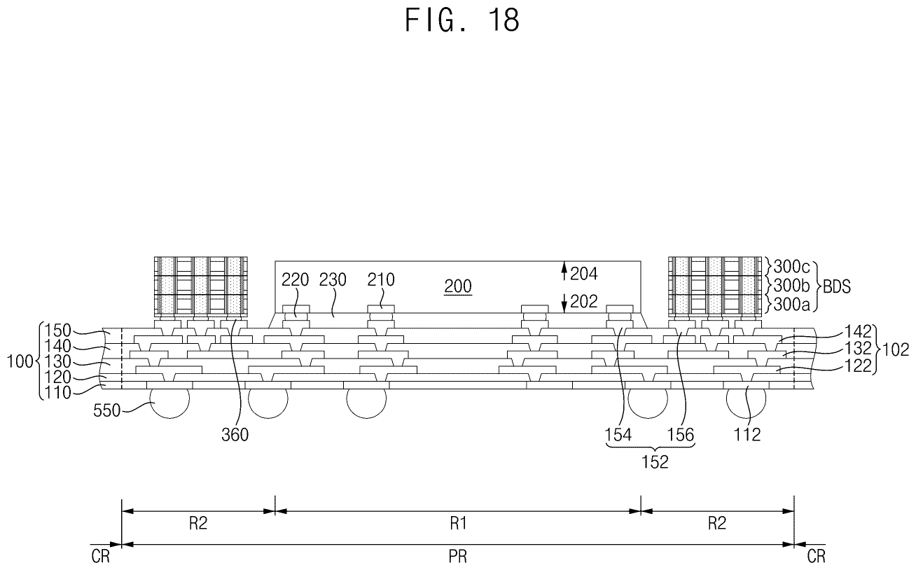

As illustrated in FIG. 17, the stacked first to third silicon substrates 310a, 310b, and 310c may be individually separated to form a bridge die stack BDS. The individually separated bridge die stack BDS may have a plurality of stacked first to third bridge dies 300a, 300b, and 300c.

A sawing process may be performed to individually separate the first to third silicon substrates 310a, 310b, and 310c to form bridge die stacks BDS having a desired shape. Each of the bridge die stacks BDSs may include a plurality of stacked first to third bridge dies 300a, 300b, and 300c. When viewed from a plan view, the bridge die stack BDS may have a square or rectangular shape.

The first through-vias 332a may be arranged in an array form in the first bridge die 300a. The second through-vias 332b may be arranged in an array form in the second bridge die 300b. The third through-vias 332c may be arranged in an array form in the third bridge die 300c. The arrangement of the first through-vias 332a of the first bridge die 300a, the arrangement of the second through-vias 332b of the second bridge die 300b, and the arrangement of the third through-vias 332c of the third bridge die 300c may correspond to each other.

Referring to FIGS. 18 and 19, the bridge die stacks BDSs may be disposed on the second region R2 on the lower redistribution wiring layer 100. Specifically, the bridge die stack BDS may be disposed on the lower redistribution wiring layer 100 via second conductive bumps 360. The connection pad 354 formed on the first surface 312a of the first silicon substrate 310a of the bridge die stack BDS may be electrically connected to the bridge connection bonding pad 156 by the second conductive bumps 360. For example, the second conductive bumps 360 may include a micro bump uBump. Thus, the first redistribution wirings 102 of the lower redistribution wiring layer 100 may be electrically connected to the first to third through-vias 332a, 332b, and 332c sequentially stacked in the bridge die stack BDS.

As illustrated in FIG. 19, each of the bridge die stacks BDS may have a rectangular shape having a short side and a long side. The third through-vias 332c may be arranged in a predetermined array shape in the third bridge die 300c. For example, a plurality of third through-vias 332c may be arranged in an array shape so as to be spaced apart from each other at a predetermined interval to have a plurality of rows and a plurality of columns.

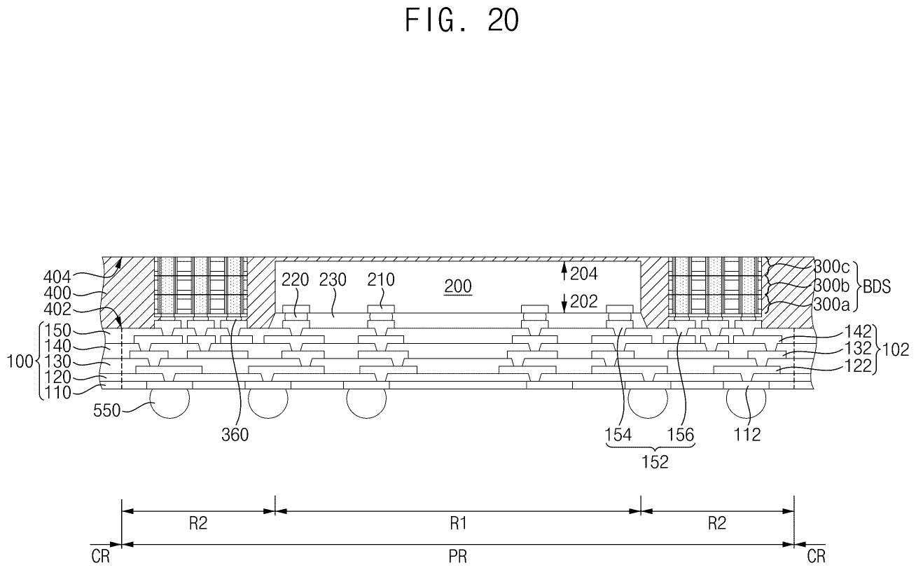

Referring to FIG. 20, a sealing member 400 may be formed on the upper surface of the lower redistribution wiring layer 100 to cover the semiconductor chip 200 and the plurality of bridge die stacks BDS.

First, the sealing material may be formed to cover the upper surface 204 of the semiconductor chip 200 and the upper surfaces of the bridge die stacks BDS. For example, the sealing material may include an epoxy mold compound (EMC). The sealing material may include a UV resin, a polyurethane resin, a silicon resin, a silica filler, or combinations thereof.

Subsequently, an upper portion of the sealing material may be partially removed to form the sealing member 400 exposing upper surfaces of the bridge die stacks BDS. Specifically, the sealing material may be partially removed so that the third through-vias 332c are exposed on the second surface 314c of the third bridge die 300c positioned at the uppermost end of the bridge die stack BDS. A grinding process may be performed to partially remove an upper portion of the sealing material.

The sealing member 400 may include a first sealing portion covering the upper surface 204 of the semiconductor chip 200 and a second sealing portion covering the upper surface of the lower redistribution wiring layer 100 around the semiconductor chip 200.

Accordingly, the bridge die stack BDS may extend to penetrate the sealing member 400 on the upper surface of the fan-out region R2 of the lower redistribution wiring layer 100. The first to third through-vias 332a, 332b, and 332c sequentially stacked in the bridge die stack BDS may serve as a through mold via TMV formed to penetrate the second sealing portion of the sealing member 400.

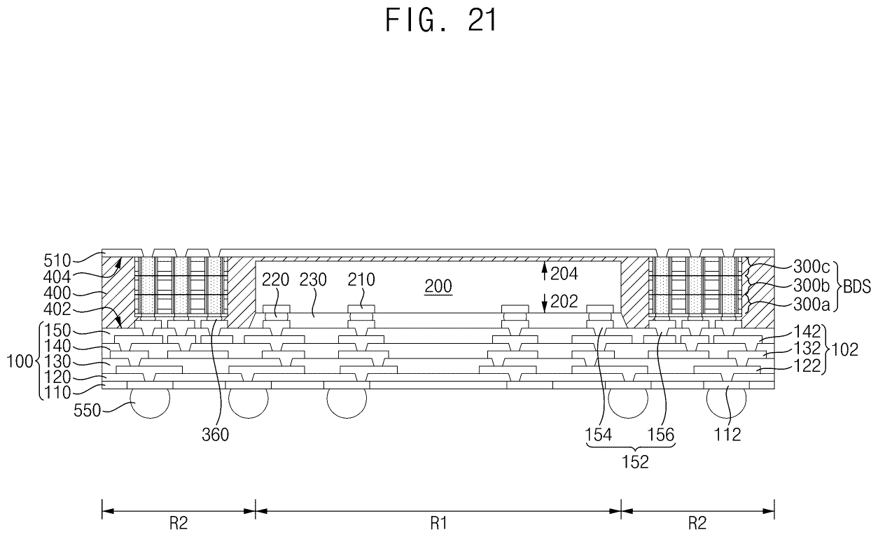

Referring to FIG. 21, an upper redistribution wiring layer 500 having second redistribution wirings 502 electrically connected to the first to third through-vias 332a, 332b, and 332c sequentially stacked in the bridge die stack BDS may be formed on the upper surface 404 of the sealing member 400.

In some example embodiments, a first upper insulating layer 510 may formed on the upper surface 404 of the sealing member 400, and then the first upper insulating layer 510 may be patterned to form openings exposing upper ends of the third through-vias 332a, 332b, and 332c of the bridge die stack BDS, respectively. The openings of the patterned first upper insulating layer 510 may expose upper surfaces of the third through-vias 332a, 332b, and 332c of the bridge die stack BDS.

Subsequently, after a seed layer is formed on portions of the exposed third through-vias 332a, 332b, and 332c of the bridge die stack BDS and in the openings, the seed layer may be patterned and an electroplating process may be performed to form first upper redistribution wirings 512. Accordingly, at least portions of the first upper redistribution wirings 512 may be electrically connected to the third through-vias 332a, 332b, and 332c of the bridge die stack BDS through the openings.

Then, after a second upper insulating layer 520 is formed on the first upper insulating layer 510, the second upper insulating layer 520 may be patterned to form openings exposing the first upper redistribution wirings 512. Then, second upper redistribution wirings 522 which are in contact, for example direct contact, with the first upper redistribution wirings 512 through the openings may be formed on the second upper insulating layer 520.

Accordingly, the second redistribution wirings 502 may include at least two layers of first upper redistribution wirings 512 and second upper redistribution wirings 522. In this case, the second upper redistribution wirings 522 may correspond to the uppermost redistribution wirings among the second redistribution wirings.

Subsequently, upper bonding pads (not illustrated) may be formed on the second upper redistribution wirings 522 as the uppermost redistribution wirings, respectively, and a third upper insulating layer 530 exposing at least a portion of the upper bonding pad on the second upper redistribution wirings 522 may be formed on the second upper insulating layer 520. The third upper insulating layer 530 may serve as a passivation layer.

Then, the carrier substrate C1 may be removed, and the external connection members 550 may be formed on the outer surface of the lower redistribution wiring layer 100, that is the first bonding pads 112 on the lower surface.

Then, the lower redistribution wiring layers 100 may be separated individually by a sawing process to complete the fan-out wafer level package 10 of FIG. 1 including the sealing member 400, the lower redistribution wiring layer 100 formed on the lower surface 402 of the sealing member 400 and the upper redistribution wiring layer 500 formed on the upper surface 402 of the sealing member 400.

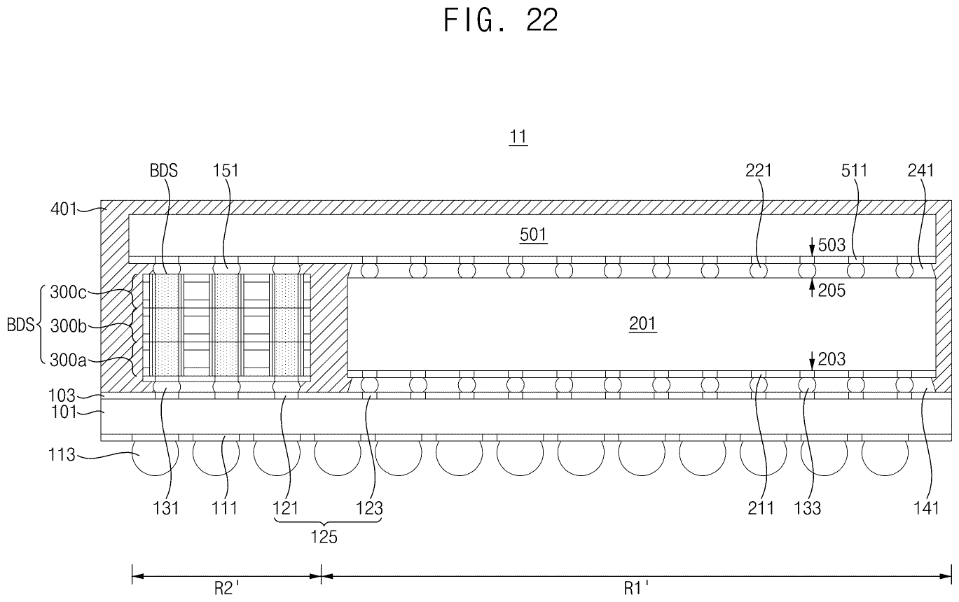

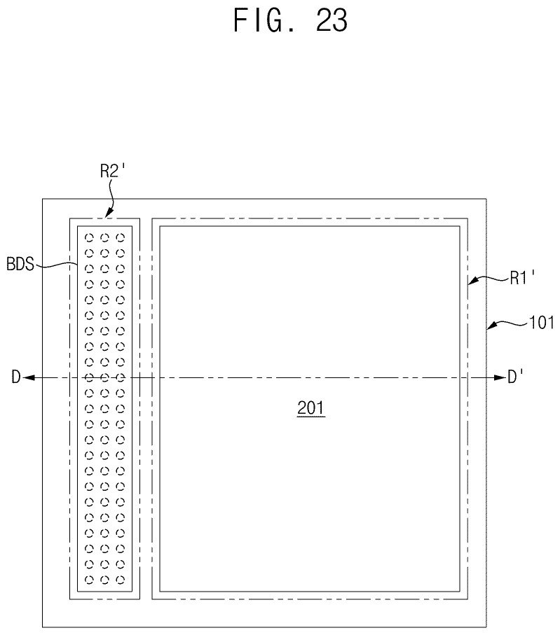

FIG. 22 is a cross-sectional view illustrating a semiconductor package in accordance with some example embodiments. FIG. 23 is a plan view illustrating the first semiconductor chip and a bridge die stack disposed on a package substrate of FIG. 22. FIG. 22 is a cross-sectional view taken along the line D-D′ of FIG. 23.

Referring to FIGS. 22 and 23, a semiconductor package 11 may include a package substrate 101, a first semiconductor chip 201 disposed on the package substrate 101, at least one bridge die stack BDS disposed on the package substrate 101 to be spaced apart from the first semiconductor chip 201 and electrically connected to the package substrate 101, and a second semiconductor chip 501 disposed on the first semiconductor chip 201 and at least one bridge die stack BDS. In addition, the semiconductor package 11 may further include a sealing member 401 covering the first and second semiconductor chips 201 and 501 and at least one bridge die stack BDS on the package substrate 101, external connection members 113 for electrical connection with an external device, etc.

In some example embodiments, the first semiconductor chip 201 may include a memory device, and the second semiconductor chip 501 may include a logic semiconductor device. Alternatively, the first semiconductor chip 201 may include a logic semiconductor device, and the second semiconductor chip 501 may include a memory device. The logic semiconductor device may be an ASIC as a host such as a CPU, a GPU, and/or an SoC. The memory device may include a high bandwidth memory (HBM) device. The semiconductor package 11 may include a 3D structure semiconductor memory device.

In some example embodiments, the package substrate 101 may have an upper insulating layer 103 and an upper substrate pads 125 on an upper surface thereof. When viewed from a plan view, the package substrate 101 may include a first region R1′ overlapping the first semiconductor chip 201 mounted on the upper surface of the package substrate 101 and a second region R2′ adjacent to the first region R1′ on the package substrate 101.

The upper substrate pads 125 may be exposed from the upper surface of the package substrate 101. The upper substrate pads 125 may include chip connection bonding pads 123 disposed in the first region R1′ and bridge connection substrate pads 121 disposed in the second region R2′.

The first semiconductor chip 201 may have a first surface 203 facing the package substrate 101 and a second surface 205 opposite to the first surface 203. The first semiconductor chip 201 may have a first surface 203, that is, a plurality of first chip pads 211 on an active surface. The first semiconductor chip 201 may be mounted on the first region R1′ of the package substrate 101 such that the first surface, on which the first chip pads 211 are formed, faces the package substrate 101.

The semiconductor chip 201 may be mounted on the package substrate 101 by a flip chip bonding method. The semiconductor chip 201 may be mounted on the package substrate 101 via first conductive bumps 133. The first conductive bump 133 may be disposed between the chip connection bonding pad 123 on the package substrate 101 and the first chip pad 211 of the first semiconductor chip 201 to electrically connect the first semiconductor chip 201 and the package substrate 101. For example, the first conductive bump 133 may include a pillar bump formed on the first chip pad 211 of the first semiconductor chip 201 and a solder bump formed on the pillar bump. Alternatively, the first conductive bump 133 may include a solder bump formed on the first chip pad 211 of the first semiconductor chip 201.

A first underfill member 141 may be disposed between the first semiconductor chip 201 and the package substrate 101. The first underfill member 141 may include a material having relatively high fluidity to effectively fill a small space between the first semiconductor chip 201 and the package substrate 101. For example, the first underfill member 141 may include an adhesive including an epoxy material.

In some example embodiments, the bridge die stack BDS may be formed to vertically extend on the bridge connection substrate pad 121 on the second region R2′ of the package substrate 101. The bridge die stack BDS may be disposed on the package substrate 101 via a lower conductive bumps 131. The bridge die stack BDS may be electrically connected to the bridge connection substrate pads 121 by the lower conductive bumps 131. A height of the bridge die stack BDS may be adjusted by the thickness of the first semiconductor chip 201 and the number of bridge dies 300 to be stacked. An upper surface of the bridge die stack BDS may be coplanar to a second surface 205 of the first semiconductor chip 201.

As shown in FIG. 23, when viewed from a plan view, the first semiconductor chip 201 may be disposed on the first region R′, and the bridge die stack BDS may be disposed on the second region R2′. The bridge die stack BDS may be disposed to be spaced apart from the first semiconductor chip 201.

The bridge die stack BDS may include a configuration substantially the same as or similar to that of the bridge die stack BDS described in FIG. 1. Thus, a redundant description thereof will be omitted.

The second semiconductor chip 501 may be disposed to overlap the first region R1′ and the second region R2′. The second semiconductor chip 501 may be mounted on the upper surface of the bridge die stack BDS and the second surface 205 of the first semiconductor chip 201 by a flip chip bonding method. The second semiconductor chip 501 may be disposed on a front surface 503, on which second chip pads 511 are formed, that is, the active surface thereof faces the upper surface of the bridge die stack BDS. The second chip pads 511 of the second semiconductor chip 501 may be electrically connected to the first semiconductor chip 201 by second conductive bumps 221, and may be electrically connected to the bridge die stack BDS by upper conductive bumps 151. Thus, the bridge die stack BDS may electrically connect the package substrate 101 to the second semiconductor chip 501. In this case, the first semiconductor chip 201 may include through-vias and rear chip pads provided on the upper surface of the first semiconductor chip 200 and electrically connected to the through-vias, and the through-vias may electrically connect the chip pads 211 to the rear chip pads. Alternatively, the second semiconductor chip 501 may be electrically connected to the bridge die stack BDS and electrically insulated from the first semiconductor chip 201. In this case, the second conductive bumps 221 may be dummy bumps for supporting the second semiconductor chip 501.

A second underfill member 241 may be underfilled between the second semiconductor chip 501 and the first semiconductor chip 201. The second underfill member 241 may include a material having relatively high fluidity to effectively fill the small space between the second semiconductor chip 501 and the first semiconductor chip 201. For example, the second underfill member 241 may include an adhesive including an epoxy material.

The sealing member 401 may be provided on the package substrate 101 to cover the first semiconductor chip 201, the bridge die stack BDS, and the second semiconductor chip 501. The external connection members 113 may be disposed on the bonding pads 111 on the bottom surface of the package substrate.

As described above, the semiconductor package 11 as a 3D package may include a package substrate 101, a first semiconductor chip 201 disposed on the package substrate 101, a bridge die stack BDS disposed on the package substrate 101 to be spaced apart from the first semiconductor chip 201 and electrically connected to the package substrate 101, and a second semiconductor chip 501 disposed on the first semiconductor chip 201 and the bridge die stack BDS.

Through this, the bridge die stack BDS has finer wiring in the region outside the semiconductor chip, and there is no need to have a TSV inside the semiconductor chip, so it is possible to increase the yield of the semiconductor chip and improve the performance of the semiconductor chip by increasing the integration of the semiconductor chip.

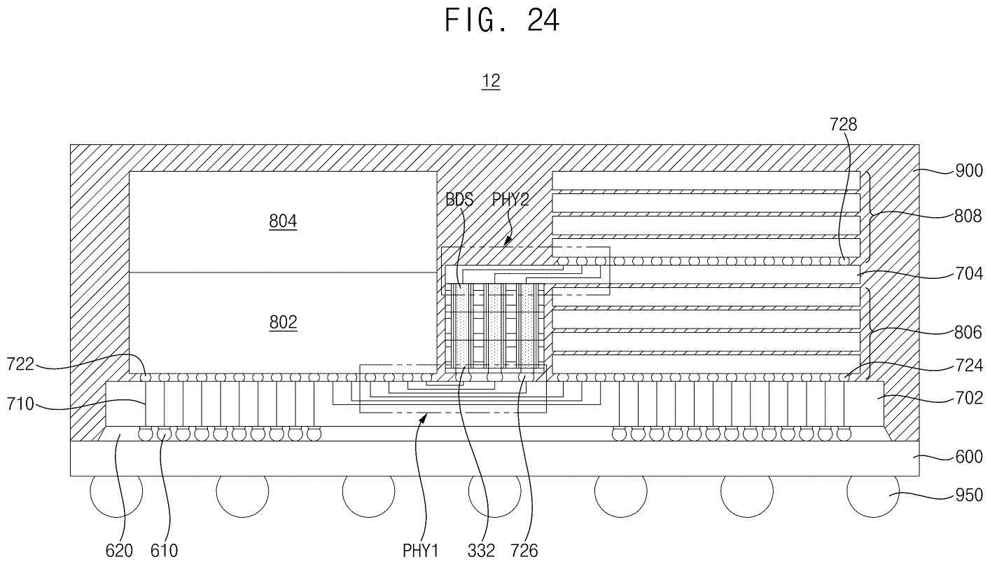

FIG. 24 is a cross-sectional view illustrating a semiconductor package in accordance with some example embodiments.

Referring to FIG. 24, a semiconductor package 12 may include a package substrate 600, a first interposer 702 disposed on the package substrate, a first semiconductor device 802 disposed on the first interposer 702, a second semiconductor device 804 disposed on the first semiconductor device 802, a third semiconductor device 806 disposed on the first interposer 702 spaced apart from the first semiconductor device 802, a bridge die stack BDS disposed between the third semiconductor device 806, a second interposer 704 disposed on the second interposer 704, and a fourth semiconductor device 808 disposed on the second interposer 704. In addition, the semiconductor package 12 may further include external connection members 950 for electrical connection between the sealing member 900 and the external device.

In some example embodiments, the semiconductor package 12 may be a memory module having a stacked chip structure in which a plurality of dies (chips) are stacked. For example, the semiconductor package 12 may include a semiconductor memory device having a 2.5D chip structure. The semiconductor package 12 including the memory device having a 2.5D chip structure may include first and second interposer 702 and 704 for electrically connecting the first to fourth semiconductor devices 802, 804, 806, and 808.

In this case, the first and second semiconductor devices 802 and 804 may include a logic semiconductor device, and the third and fourth semiconductor devices 806 and 808 may include a memory device. The logic semiconductor device may be an ASIC as a host such as a CPU, a GPU, and/or an SoC. The memory device may include a high bandwidth memory (HBM) device.

The first interposer 702 may be disposed on the package substrate 600. The first interposer 702 may be mounted on the package substrate 600 via a plurality of conductive bumps 610. An underfill member 620 may be underfilled between the package substrate 600 and the first interposer 702. The first interposer 702 may include a plurality of through-vias 710 therein. The first interposer 702 may include a first physical circuit region PHY1 including a bridge die stack BDS and redistribution wirings for electrical connection with the first and third semiconductor devices 802 and 806. The first interposer 702 may include connection wires connected therein. The first semiconductor device 802, the third semiconductor device 806, and the bridge die stack BDS may be connected to each other through redistribution wirings in the first physical circuit region PHY1 and the connection wires in the first interposer 702, or may be electrically connected to the package substrate 600.

The first semiconductor device 802 and the second semiconductor device 804 may be sequentially stacked on the first interposer 702. The first semiconductor device 802 may include a chip pad on the front surface facing the first interposer, that is, on an active surface. The first semiconductor device 802 may be mounted on the first interposer 702 via the conductive bumps 722, such that the active surface faces the first interposer 702. The first semiconductor device 802 and the through-vias of the first interposer 702 may be electrically connected through the conductive bumps. The first semiconductor device 802 may include an ASIC as a host, such as a CPU, a GPU, and/or an SoC. The second semiconductor device 804 may be disposed on the first semiconductor device 802. The second semiconductor device 804 may be a dummy chip which is not electrically connected to the first semiconductor device 802.

The third semiconductor device 806 may be disposed on the first interposer 702 to be spaced apart from the first semiconductor device 802. The first semiconductor device 806 may include a high bandwidth memory (HBM) device. The first semiconductor device 806 may include a buffer die serving as a circuit and a plurality of memory dies sequentially stacked on the buffer die. The third semiconductor device 806 may be electrically connected to the first interposer 702 through conductive bumps 724.

The bridge die stack BDS may be mounted between the first semiconductor device 802 and the third semiconductor device 806 on the first interposer 702. The bridge die stack BDS may vertically extend on the conductive bumps 726 formed on the first interposer 702. The through-vias 332 (see the drawing) of the bridge die stack BDS may be electrically connected to the first semiconductor device 802 through the wirings in the first physical circuit region PHY1 on the first interposer 702 via the conductive bumps.

The bridge die stack BDS may include a configuration substantially the same as or similar to that of the bridge die stack BDS described in FIG. 1. Thus, a redundant description thereof will be omitted.

The second interposer 704 may be provided on the third semiconductor device 806 and the bridge die stack BDS. The second interposer 704 may include a plurality of through-vias therein. The second interposer 704 may include a second physical circuit region PHY2 including connection wirings therein for electrical connection with the bridge die stack BDS and the fourth semiconductor device 808. The second interposer 704 may include connection wirings connected therein. Thus, the first semiconductor device 802, the fourth semiconductor device 808, and the bridge die stack BDS may be connected to each other through the connection wirings or may be electrically connected to the package substrate 600.

The fourth semiconductor device 808 may be disposed on the second interposer 704. The fourth semiconductor device 808 may include a high bandwidth memory (HBM) device. The fourth semiconductor device 808 may include a buffer die serving as a circuit and a plurality of memory dies sequentially stacked on the buffer die. The fourth semiconductor device 808 may be electrically connected to the second interposer through the conductive bumps 728. Furthermore, the fourth semiconductor device 808 may be electrically connected to the bridge die stack BDS through the connection wirings provided in the second physical circuit region PHY2 in the second interposer 704 through the conductive bumps. That is, the fourth semiconductor device 808 may be electrically connected to the package substrate 600 and the first semiconductor device 802 through the bridge die stack BDS.

Then, the sealing member 900 may cover at least portions of the first to fourth semiconductor devices 802, 804, 806, and 808 on the upper surface of the package substrate 600. For example, the sealing member 900 may include an epoxy mold compound (EMC). The sealing member 900 may be formed by a sealing process, a screen printing process, a lamination process, etc. The external connection members 950 may be disposed on bonding pads on the lower surface of the package substrate 600.

The semiconductor package may include semiconductor devices such as logic devices or memory devices. The semiconductor package may include logic devices such as central processing units (CPUs), main processing units (MPUs), or application processors (APs), etc., and volatile memory devices such as DRAM devices, HBM devices, or non-volatile memory devices such as flash memory devices, PRAM devices, MRAM devices, ReRAM devices, etc.

The foregoing is illustrative of some example embodiments and is not to be construed as limiting thereof. Although a few example embodiments have been described, those skilled in the art will readily appreciate that many modifications are possible in example embodiments without materially departing from the novel teachings and advantages of the present inventive concepts. Accordingly, all such modifications are intended to be included within the scope of example embodiments as defined in the claims.

What is claimed is:

1. A semiconductor package comprising:
a lower redistribution wiring layer having first redistribution wirings, the lower redistribution wiring layer having a first region and a second region surrounding the first region;
a semiconductor chip on the first region of the lower redistribution wiring layer and electrically connected to the first redistribution wirings;
at least one bridge die stack on the second region of the lower redistribution wiring layer and including a plurality of bridge dies sequentially stacked on one another, each of the bridge dies including a plurality of through-vias that are electrically connected to the first redistribution wirings;
a sealing member on the lower redistribution wiring layer covering the semiconductor chip and the at least one bridge die stack; and
an upper redistribution wiring layer on the sealing member and including second redistribution wirings electrically connected to the through-vias of the at least one bridge die stack.

2. The semiconductor package of claim 1, wherein the at least one bridge die stack has a rectangular shape when viewed from a plan view.

3. The semiconductor package of claim 1, wherein the plurality of the through-vias are arranged in an array within each of the bridge dies when viewed from a plan view.

4. The semiconductor package of claim 1, wherein each of the bridge dies of the at least one bridge die stack comprises:
a silicon substrate having a first surface and a second surface opposite to the first surface;
the plurality of through-vias penetrating the silicon substrate;
a first insulating layer in the first surface of the silicon substrate exposing first ends of the plurality of through-vias; and
a second insulating layer in the second surface of the silicon substrate exposing second ends of the plurality of through-vias.

5. The semiconductor package of claim 4, wherein
a first insulating layer of a first bridge die among the bridge die stacks and a second insulating layer of a second bridge die stacked on the first bridge die are bonded to each other, and
a through-via of the first bridge die and a corresponding through-via of the second bridge die are bonded to each other.

6. The semiconductor package of claim 4, wherein the first insulating layer and the second insulating layer include silicon oxide, silicon nitride, or silicon carbon nitride.

7. The semiconductor package of claim 4, wherein the at least one bridge die stack further comprises:
a plurality of connection pads, each connection pad of the plurality of connection pads respectively on the second ends of the plurality of the through-vias on a second insulating layer of a lowermost bridge die; and
a protective layer on the second insulating layer of the lowermost bridge die exposing the plurality of connection pads.

8. The semiconductor package of claim 7, wherein the at least one bridge die stack further includes a plurality of conductive bumps each respectively on the plurality of connection pads.

9. The semiconductor package of claim 1, wherein each of the through-vias has a diameter within a range of 100 μm to 300 μm.

10. The semiconductor package of claim 1, wherein each of the through-vias has a height within a range of 380 μm to 760 μm.

11. A semiconductor package comprising:
a package substrate;
a first semiconductor chip on the package substrate;
at least one bridge die stack spaced apart from the first semiconductor chip on the package substrate, the at least one bridge die including a plurality of through-vias that are each respectively electrically connected to substrate pads of the package substrate; and
a second semiconductor chip on the first semiconductor chip and the at least one bridge die stack, the second semiconductor chip electrically connected to the through-vias.

12. The semiconductor package of claim 11, wherein the at least one bridge die stack has a rectangular shape when viewed from a plan view.

13. The semiconductor package of claim 11, wherein the plurality of the through-vias are arranged in an array within each of the bridge dies in a plan view.

14. The semiconductor package of claim 11, wherein each of the bridge dies of the at least one bridge die stack comprises:
a silicon substrate having a first surface and a second surface opposite to the first surface;
the plurality of through-vias penetrating the silicon substrate;
a first insulating layer in the first surface of the silicon substrate exposing first ends of the plurality of through-vias; and
a second insulating layer in the second surface of the silicon substrate exposing second ends of the plurality of through-vias.

15. The semiconductor package of claim 14, wherein
a first insulating layer of a first bridge die among the bridge die stacks and a second insulating layer of a second bridge die stacked on the first bridge die are bonded to each other, and
a through-via of the first bridge die and a corresponding through-via of the second bridge die are bonded to each other.

16. The semiconductor package of claim 14, wherein the at least one bridge die stack further comprises:
a plurality of connection pads respectively on the second ends of the plurality of the through-vias on a second insulating layer of a lowermost bridge die; and
a protective layer on the second insulating layer of the lowermost bridge die and exposing the plurality of connection pads.

17. The semiconductor package of claim 16, wherein the at least one bridge die stack further includes conductive bumps each respectively on the plurality of connection pads.

18. The semiconductor package of claim 11, wherein each of the through-vias has a diameter within a range of 100 μm to 300 μm.

19. The semiconductor package of claim 11, wherein each of the through-vias has a height within a range of 380 μm to 760 μm.

20. A semiconductor package comprising:
a first redistribution wiring layer having first redistribution wirings, the first redistribution wiring layer having a chip mounting region and a peripheral region surrounding the chip mounting region;
a semiconductor chip on the chip mounting region of the first redistribution wiring layer;
a plurality of bridge die stacks on the peripheral region of the first redistribution wiring layer, each bridge die stack including a plurality of sequentially stacked bridge dies, each bridge die including a plurality of through-vias configured to be electrically connected to substrate pads of a package substrate;
a sealing member covering the semiconductor chip and the plurality of bridge die stacks on the first redistribution wiring layer; and
a second redistribution wiring layer on the sealing member and including a second redistribution wirings electrically connected to the through-vias.
